(19) United States
(12) Patent Application Publication
(10) Pub. No.: US 2008/0128797 A1
(43) Pub. Date: Jun. 5, 2008

(54) STRUCTURE AND METHOD FOR MULTIPLE HEIGHT FINFET DEVICES

(75) Inventors: Thomas W. Dyer, Pleasant Valley, NY (US); Haining S. Yang, Wappingers Falls, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/565,136

(22) Filed: Nov. 30, 2006

(51) Int. Cl. H01L 29/78

(52) U.S. Cl. 257/328; 257/E29.262

(57) ABSTRACT

Multiple finFETs containing semiconductor fins with the same height for the top but with different heights for the bottom are formed. Patterned oxygen implant masks are used to form a buried oxide layer with at least two different levels of oxide top surface. After the formation of the buried oxide layer, the top semiconductor layer has a substantially level top surface. Fins are formed by lithographically patterning and etching the top semiconductor layer. The resulting fins may be semiconductor fins with different heights or fins comprising an upper portion of semiconductor fins and a lower portion of oxide fins. In both cases, semiconductor fins of different heights are used to form finFETs with fractional on-current of a full height finFET.

### FIELD OF THE INVENTION

The present invention relates to semiconductor devices, and particularly, to finFET devices with multiple fin heights.

### BACKGROUND OF THE INVENTION

A FinFET transistor is a MOSFET transistor in which a “fin” structure is formed out of a semiconductor material and a channel is formed underneath the surface of the fin structure. In a typical finFET structure, at east one horizontal channel is formed on a vertical sidewall within a semiconductor “fin” that is set sideways, or edgewise, upon a substrate. Generally, the fin comprises a single crystalline semiconductor material with a substantially rectangular cross-sectional area.

The fin is typically thin, that is, the dimension of the fin perpendicular to the plane of the channel is small relative to the channel length. Furthermore, multiple channels may be formed utilizing the multiple surfaces of the fin with a common gate electrode. For example, a double gate finFET utilizes a double gate configuration in which the gate electrode is placed on two opposite sides of the fin. Triple gate finFETs and quadruple gate finFETs with more sides of the fin contacting the gate electrode are also known in the art. The increased number of sides from which the gate electrode controls the channel of the finFET enhances the controllability of the channel in a finFET compared to a planar MOSFET. The improved control of the channel allows smaller device dimensions with less short channel effects as well as a larger electrical current that can be switched at high speeds. A finFET device has faster switching speeds, an equivalent or higher current density, and improved short channel control compared to mainstream planar CMOS technology utilizing similar critical dimensions.

Despite improved MOSFET performance, finFETs, however, present unique design challenges. This is because the fins are typically manufactured with the same height. While the planar MOSFET devices may have an arbitrary width above the minimum dimension that each technology node enables, and therefore have on-currents that are arbitrarily scalable in an analog scale without changing the transistor characteristics, finFETs cannot achieve such scalability, that is, the on-current may not be increased by an arbitrary numerical factor. The on-current of a finFET can be adjusted only by integer multiples of the on-current of a unit finFET without changing the transistor characteristics unless the gate length is changed along with the accompanying changes in the transistor characteristics. The lack of scalability of the on-current of a finFET without changing the transistor characteristics thus remains a challenge in utilization of finFETs in the semiconductor industry.

Therefore, there exists a need for a semiconductor structure and a manufacturing process that enhances the scalability of the on-current of finEET devices while preserving the transistor characteristics.

Specifically, there exists a need for enabling a non-integer multiple of a unit finFET on-current without altering the transistor characteristics.

Also, there exists a need to achieve enhanced scalability of a finFET on-current in an economical way, that is, with minimum process complexity and minimum incremental cost.

### SUMMARY OF THE INVENTION

The present invention addresses the needs described above and provides structures and methods of forming finFET devices with multiple vertical dimensions for semiconductor fins with minimum process complexity and minimum incremental cost.

According to the present invention, a first semiconductor structure is provided. The first semiconductor structure comprises:

a semiconductor substrate;

an oxide layer located directly on the semiconductor substrate and having at least two different levels of an oxide top surface;

at least two semiconductor fins, each with a fin top surface and a fin bottom surface, wherein the fin top surfaces have substantially the same height and the fin bottom surfaces have substantially different heights and the fin bottom surfaces adjoin the oxide layer; and

at least two semiconductor finFETs which include the at least two semiconductor fins.

The oxide layer is a buried oxide layer formed within an initial semiconductor substrate out of which the semiconductor substrate mentioned above is formed. Preferably, the initial semiconductor substrate is an epitaxial semiconductor substrate comprising a first epitaxial semiconductor material. As a consequence, the semiconductor substrate mentioned above is also an epitaxial semiconductor substrate comprising a first epitaxial semiconductor material, It must be noted, however, that one of ordinary skill in the art may introduce a low level doping of other semiconductor material, such as carbon or germanium, to convert a portion of the initial semiconductor substrate to an altered semiconductor material.

At least a portion of the buried oxide layer is formed by a SIMOX (Separation by Implantation of Oxygen) process. That is, the initial semiconductor substrate may be a bulk substrate or the initial semiconductor wafer may be an SOI (silicon on insulator) wafer. In both cases, at least one oxygen implant mask is formed on the initial semiconductor substrate and oxygen is implanted into the initial semiconductor substrate. Due to the presence of oxygen implantation masks, the buried oxide layer thus formed after the oxygen implantation and a subsequent anneal has at least two different levels of an oxide top surface. Since the top semiconductor layer adjoins the buried oxide layer, the bottom surface of the top oxide layer is the top surface of the buried oxide layer, and therefore, the bottom surface of the top oxide layer also has at least two different levels.

According to the first embodiment of the present invention, at least one oxygen implant mask is formed on the initial semiconductor substrate and lithographically patterned. Implanting oxygen in the initial semiconductor substrate produces a buried oxide layer with multiple levels, that is, with multiple depths from the top surface of the resulting top semiconductor layer In general, multiple lithographically patterned oxygen implant masks may be formed as a stack prior to implanting oxygen into the initial semiconductor substrate. Despite the presence of the multiple levels, the buried oxide layer has substantially the same thickness except around boundaries where different levels are adjoined. Since the buried oxide layer has multiple levels, the “substrate top surface” of the resulting semiconductor substrate below the buried oxide has multiple levels corresponding to the multiple levels of the buried oxide. The top surface of the top semiconductor layer formed over the buried oxide layer has the same height despite the different depths of the buried oxide layer across the structure since the amount of the implanted oxygen and consequently the increase in volume of the structure is the same irrespective of the depth of the implanted oxygen species.

According to the second embodiment of the present invention, formation of a lithographically patterned oxygen implant mask and an oxygen implantation is performed at least once on a structure containing an existing buried oxide layer. For example, if the initial substrate is a bulk substrate, formation of a lithographically patterned oxygen implant mask and oxygen implantation is performed at least twice. In the case of an SOI initial semiconductor substrate, the above process is performed at least once. In general, forming a lithographically patterned implant mask and implanting oxygen may be repeated more than once. The oxygen implant energy is adjusted such that the bottom of the buried oxide layer is maintained at a constant level. The resulting structure has a buried oxide layer that has at least two substantially different levels of oxide top surface but has substantially the same level of oxide bottom surface. Consequently, the resulting semiconductor substrate under the buried oxide layer has a substantially flat “substrate top surface.” Furthermore, ignoring the volume expansion due to implanted oxygen species, the top semiconductor layer has a substantially flat top surface. If the topographic variation in the height of the top surface becomes noticeable, chemical mechanical polishing (CMP) is optionally used to make the top surface of the top semiconductor layer substantially flat.

According to the first and second embodiments of the present invention, the top semiconductor layer is lithographically patterned and etched to form at least two semiconductor fins, which are located on at least two different levels of oxide top surface. A selective reactive ion etching (RIE) is employed to etch the top semiconductor layer selective to the buried oxide layer. The etch removes all of the unmasked portions of the top semiconductor layer but does not substantially remove the buried oxide layer.

The fin bottom surfaces, or the bottom surfaces of the semiconductor fins, have substantially different “heights.” However, the fin top surfaces, or the top surfaces of the semiconductor fins, have substantially the same height. If the initial semiconductor substrate is an epitaxial semiconductor substrate, the semiconductor fins are also epitaxial at this point since optional modification of composition by implanting other semiconductor species such as carbon or germanium still preserves epitaxial alignment of the semiconductor material.

According to the third embodiment of the present invention, a second semiconductor structure is provided. The second semiconductor structure comprises:

a semiconductor substrate;

an oxide layer located directly on the semiconductor substrate;

at least two fins, each having an upper semiconductor portion with a fin top surface and at least one having a lower oxide portion disposed directly underneath the upper semiconductor portion, wherein the fin top surfaces have substantially the same heights, the upper semiconductor portions have different vertical lengths, and the at least two fins adjoin the oxide layer; and

at least two semiconductor finFETs which include the at least two fins.

According to the third embodiment, the methods for forming the structure according to the first or second embodiment of the present invention is followed with exactly the same structures until the formation of buried oxide is finished and the top semiconductor layer is lithographically patterned prior to the etch that forms at least two semiconductor fins. The etch employs a non-selective reactive ion etching (RIE) that etches both the top semiconductor layer and buried oxide layer. At least one of the resulting fins has both an upper semiconductor portion, which is identical to the semiconductor fins of the first and the second embodiments, and a lower oxide portion, which is not present in the first or second embodiment.

The oxide portion is formed by etching the buried oxide layer in the area not masked by the patterned resist and leaving the portion of the buried oxide layer underneath the upper semiconductor portion intact, According to the third embodiment of the present invention, the etch results in at least two fins, each of which has an upper semiconductor portion with a fin top surface. The upper semiconductor portion itself is a semiconductor fin and is substantially identical to the semiconductor fins according to the first and the second embodiments. The top of each fin contains a semiconductor fin. There is at least one fin that has a lower oxide portion, or an “oxide fin,” that is disposed directly underneath the upper semiconductor portion. The structure has at least two upper semiconductor portions that have different vertical lengths, that is, different distances between the top surface of the upper semiconductor portion and the bottom surface of the upper semiconductor portion. At least one fin is a stack of a semiconductor fin and an oxide fin wherein the semiconductor fin is located directly over the oxide fin.

Preferably, the at least two upper semiconductor portions comprise a second epitaxial semiconductor material. Discussions on the epitaxial structure of the at least two semiconductor fins according to the first and the second embodiments apply to the at least two upper semiconductor portions according to the third embodiment.

According to the first, second, and the third embodiments of the present invention, at least two semiconductor finFETs which include the at least two semiconductor fins are formed. All three embodiments enable either semiconductor fins with different vertical lengths or upper semiconductor portion with different vertical lengths. Utilizing the multiple vertical lengths of the semiconductor structures thus obtained, i.e., semiconductor fins or upper semiconductor portions, finFETS with different vertical length, and consequently with different on-current are formed.

A gate dielectric is formed either by deposition or growth on the sidewalls of the semiconductor fins of both types followed by deposition and patterning of a gate conductor stack to form a gate electrode. If a thick insulator layer is disposed on and above the top surfaces of the semiconductor fins, a double gate finFET structure results wherein the gate control is effected only by the two sections of the gate electrode located on the gate dielectric on the two sidewalls of each of the finFETs. If an insulator layer is not disposed on and above the top surfaces of the semiconductor fins, a triple gate finFET structure results wherein the gate control is effected by the three sections of the gate electrode contacting the gate dielectric, which are located on the two sidewalls and the top surface of a finFET.

The semiconductor fins or upper semiconductor portions with the maximum vertical lengths form a finFET with a unit on-current. The semiconductor fins or upper semiconductor portions with less than the maximum vertical lengths form a finFET with a fractional on-current. The scalability of the on-current of the finFETs is thus enhanced according to the present invention.

### BRIEF DESCRIPTION OF THE DRAWINGS

FIGS. 1A-1D are sequential cross-sectional views of structures according to the first embodiment of the present invention.

FIGS. 2A 2E are sequential cross-sectional views of structures according to the second embodiment of the present invention.

FIG. 2F is a bird's eye view of a structure according to the second embodiment of the present invention.

FIG. 3 is a cross-sectional view of a structure according to the third embodiment of the present invention.

### DETAILED DESCRIPTION OF THE INVENTION

Three embodiments of the present invention are described herein.

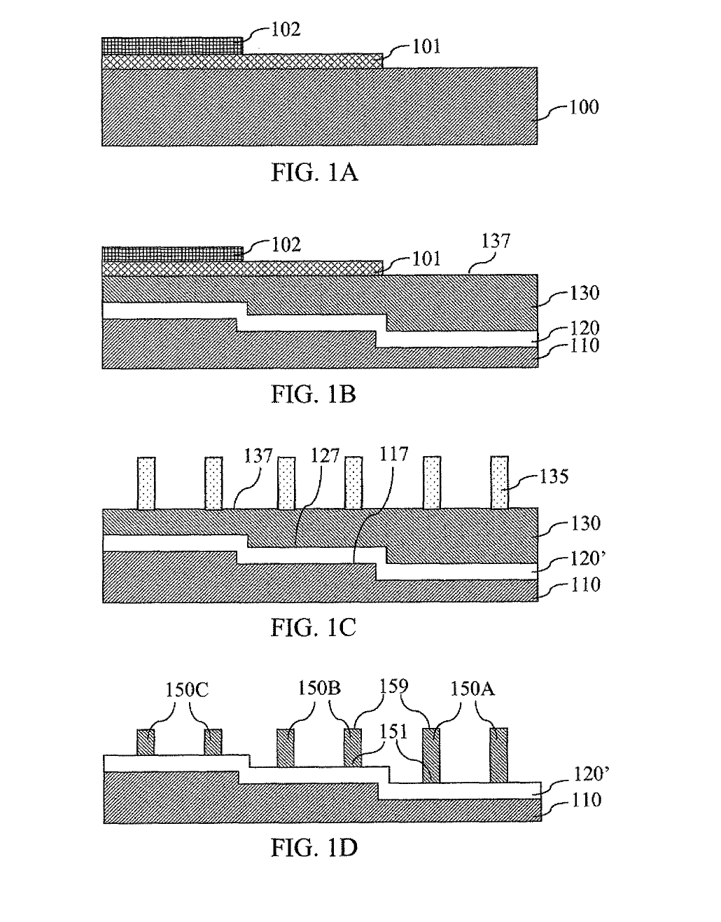

Referring to FIG. 1A, an initial semiconductor substrate 100 is provided. The initial semiconductor substrate 100 comprises a first semiconductor material. Preferably, the first semiconductor material is epitaxial, that is, has single crystalline structure. The first semiconductor material may be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. The initial semiconductor substrate 100 may be a bulk substrate, a semiconductor-on-insulator (SOI) substrate, or a hybrid substrate. While the embodiments of the present invention are described with a bulk substrate, the structure of the present invention may be formed in the top semiconductor layer of an SOI substrate, in the bulk portion of a hybrid substrate, in the top semiconductor layer in the SOI portion of a hybrid substrate.

At least one oxygen implant mask layer is formed on the top surface of the initial semiconductor substrate 100. In FIG. 1A, two oxygen implant mask layers, a first oxygen implant mask layer 101 and a second oxygen implant mask layer 102 are formed, with the first oxygen implant mask layer 101 directly contacting the initial semiconductor substrate 100 and the second implant mask layer 102 directly contacting the first oxygen implant mask layer 101. Both of the two oxygen implant mask layers are patterned.

The two oxygen implant mask layers 101, 102 may comprise the same material or different materials may be used. The two oxygen implant mask layers 101, 102 may comprise a hardmask material such as silicon dioxide, silicon nitride, silicon oxynitride, polysilicon or another dielectric material. If polysilicon is used as a hardmask material, the polysilicon is separated from the initial semiconductor substrate 100 by at least one dielectric layer. Alternatively, the two oxygen implant mask layers 101, 102 may comprise a softmask material, i.e., a photoresist. In this case, the two oxygen implant mask layers have different sensitivity to light sources of the lithography tools. The two oxygen implant masks 101, 102 may also be a combination of both. In general, a hardmask is formed prior to the formation of a softmask. In this case, the first oxygen implant mask layer 101 is a hardmask and the second oxygen implant layer 102 is a softmask.

The two oxygen implant mask layers may have the same thickness or different thicknesses may be used. All combinations of the stacking of the patterned oxygen implant layers 101, 102 over the initial semiconductor substrate 100 may be utilized to enable all available depths for oxygen implantation, that is, stacking no oxygen implant mask layer over a first area, stacking only the first oxygen implant mask layer 101 over a second area, stacking only the second oxygen implant mask layer 102 over a third area, and stacking both the first and the second oxygen implant mask layer 101, 102 over a fourth area. In general, as many oxygen implant mask layers may be used as necessary to enable different depths for the oxygen implant and to vary the depth of the buried oxide formation.

Oxygen is implanted into the initial substrate to form an oxygen rich layer 120 within the initial semiconductor substrate according to methods well known for SIMOX processes. The patterned oxygen implant mask layers 101, 102 cause the implanted oxygen to land at a lesser depth from the top surface of the initial semiconductor layer 100 compared to the area with no oxygen implant mask layer. This creates an oxygen rich layer 120 with multiple depths depending on the presence or absence of each element of the stack of oxygen implant mask layers 101, 102. Also, a portion of the initial semiconductor substrate 100 that is located above the oxygen rich layer, henceforth called a “top semiconductor layer” 130, is separated from the remaining semiconductor portion, henceforth called the “semiconductor substrate” 110, by the oxygen rich layer 120. The oxygen rich layer 120 has the same thickness across the initial semiconductor substrate 100 as shown in FIG. 1B since the dose of the oxygen implant is the same irrespective of the local presence or absence of the oxygen implant mask layers 101, 102.

The oxygen implant mask layers 101, 102 are removed by suitable methods (e.g., a wet etch if they are hardmasks, ashing if they are softmasks) and the “semiconductor top surface” 137, i.e., the top surface of the top semiconductor layer 130, is cleaned. The structure containing the oxygen rich layer 120 is then annealed to convert the oxygen rich layer 120 into a buried oxide layer 120′ as shown in FIG. 1C (but not with a patterned resist 135 yet). The annealed structure, which is formed out of the initial semiconductor substrate 100, at this point comprises the semiconductor substrate 10, the buried oxide layer 120′, and the top semiconductor layer 130. This structure has multiple levels for the first interface between the semiconductor substrate 110 and the buried oxide layer 120′ and also for the second interface between the buried oxide layer 120′ and the top semiconductor layer 130. The first interface is the “substrate top surface” 117, which is the top surface of the semiconductor substrate 110, and the “oxide bottom surface” 17, which is the bottom surface of the buried oxide layer 120′, at the same time. Consequently, the two terms, substrate top surface and oxide bottom surface, are interchangeably used herein. The second interface is the “oxide top surface” 127, which is the top surface of the buried oxide layer 120′, and the “semiconductor bottom surface” 127, which is the bottom surface of the top semiconductor layer 130. The two terms, oxide top surface and semiconductor bottom surface, are also interchangeably used herein.

Different portions of the top semiconductor layer 130 have different thicknesses and consequently, different levels for the semiconductor bottom surface 127 depending on the local presence or absence of the oxygen implant mask layers 101, 102. Similarly, different portions of the semiconductor substrate 110 have different levels for the substrate top surface 117. However, except for the regions around the boundary between two different levels for the first interface or the second interface, the thickness of the buried oxide layer 120′ is substantially the same since the thickness of the oxygen rich layer 120 was the same prior to the anneal. If the initial semiconductor substrate 100 is epitaxial, the top semiconductor layer 130 and the semiconductor substrate 110 are both epitaxial at this point. Introduction of an alloy material or dopants such as carbon or germanium may alter the composition of either the semiconductor substrate 100 or the top semiconductor layer 130. Even in these cases, however, epitaxial alignment of the semiconductor material does not change and both the semiconductor substrate 100 and the top semiconductor layer 130 have the same crystallographic orientations.

Referring to FIG. 1C, a photoresist 135 is applied to the semiconductor top surface 137 and lithographically patterned to form a pattern for fins. Optionally, a thick insulator layer (not shown) is deposited on top of the top semiconductor layer 130 prior to the patterning of the semiconductor layer. In this case, the photoresist 135 is applied to the top surface of the thick insulator layer and patterned to form a pattern for fins.

Subsequent pattern transfer into the top semiconductor layer 130 through a reactive ion etch (RIE) of the material forming the top semiconductor layer 130 selective to the underlying buried oxide layer 120′ forms semiconductor fins (150A-C) as shown in FIG. 1D. The semiconductor fins (150A-C) have different vertical lengths, that is, different distances between the fin top surface 159 of each of the semiconductor fins (150A-C) and the fin bottom surface 151 of the same semiconductor fin. In FIG. 11), three types of semiconductor fins (150A-C), that is, a full vertical length semiconductor fins 150A, a medium vertical length semiconductor fins 150B, and a short vertical length semiconductor fins 150C, are shown. Preferably, the etch removes all of the unmasked portions of the top semiconductor layer but does not substantially remove the buried oxide layer.

Each of the semiconductor fins (150A-C) has vertical sidewalls and a fin top surface 159 and a fin bottom surface 151. Preferably, both the fin top surface 159 and the fin bottom surface 151 are substantially flat. Since the top semiconductor layer out of which the semiconductor fins (150A-C) have been formed is disposed directly on top of the oxide top surface 127 which has multiple levels, the fin bottom surfaces 151 have substantially different levels, or different “heights”. The height may be defined as the absolute distance from a flat reference surface that is perpendicular to the direction of the oxygen implantation, such as a flat backside of the semiconductor substrate 110. Since the semiconductor top surface 137, which is the top surface of the semiconductor layer 130 out of which the semiconductor fins (150A-C) have been formed, is substantially flat, the fin top surfaces 159 have substantially the same height.

As discussed above, the initial semiconductor substrate is preferably an epitaxial semiconductor substrate comprising a first epitaxial semiconductor material. Optional modification by implanting other semiconductor species such as carbon or germanium to either the semiconductor substrate below the buried oxide layer or to the top semiconductor layer may alter the composition of either or both semiconductor material. Preferably, the epitaxial structure of the top semiconductor layer is preserved until the formation of the semiconductor fins. Therefore, the semiconductor fins are single crystalline in structure and comprise a second epitaxial semiconductor material. In this case, the first epitaxial semiconductor material and the second epitaxial semiconductor material have the same crystallographic orientations.

Thereafter, formation of a gate dielectric and a gate electrode follows. This part will be described below after describing the distinct parts of the second embodiment of the present invention.

According to the second embodiment of the present invention, the same initial semiconductor substrate 100 (without the oxygen implant mask layers 101, 102) as in the first embodiment of the present invention as shown in FIG. 1A is provided first. Multiple rounds of oxygen implantation are performed. Each round of oxygen implantation is performed with only one oxygen implantation mask layer or with no oxygen implantation mask layer.

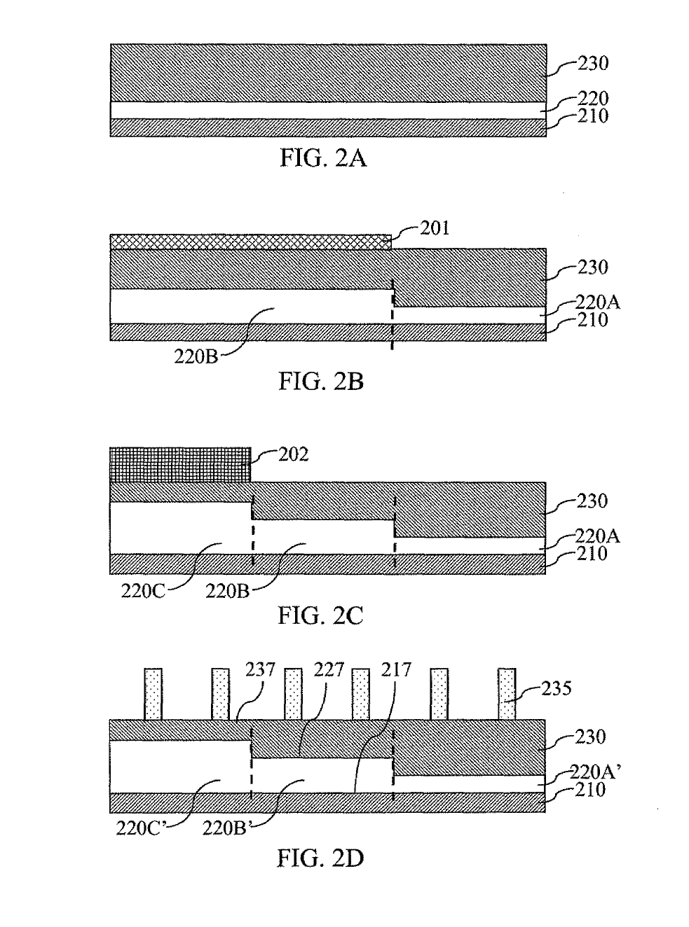

In the exemplary sequence shown in the figures, the initial semiconductor substrate 100 is implanted with oxygen to form an oxygen rich layer 220 as shown in FIG. 2A. In a manner similar to the first embodiment of the present invention, a semiconductor substrate 210 and the top semiconductor layer 230 are also formed.

A first oxygen implant mask layer 201 is deposited and patterned according to the second embodiment of the present invention. As in the first embodiment of the present invention, any of oxygen implant mask layers, including the first oxygen implant mask layer 201, may be either a hardmask or a softmask. Oxygen is thereafter implanted into the top semiconductor layer 230 to thicken a second portion of the existing oxygen rich layer 220 under the first oxygen implant mask layer 201. In the resulting structure, the oxygen rich layer 220 has two portions: a first portion 220A of the oxygen rich layer 220 that has the original thickness as in FIG. 2A and the second portion 220B of the oxygen rich layer 220 that is thicker than the first portion 220A as shown in FIG. 2B. The first oxygen implant mask layer 201 may be removed thereafter.

FIG. 2C shows a patterned second oxygen implant mask layer 202 with a different thickness than the first oxygen implant mask layer 201. Another round of oxygen implantation thickens a third portion of the existing oxygen rich layer 220 under the second oxygen implant mask layer 202. In the resulting structure, the oxygen rich layer 220 has three portions: the first portion 220A of the oxygen rich layer 220 that has the original thickness as in FIG. 2A, the second portion 220B of the oxygen rich layer 220 that has an increased thickness as first shown in FIG. 2B, and a third portion 220C of the oxygen rich layer 220 that has the twice increased thickness as shown in FIG. 2C. The second oxygen implant mask layer 202 may be removed thereafter.

While the exemplary sequence herein does not use oxygen implantation mask layer for the first oxygen implantation and uses a patterned oxygen implantation mask layer in the subsequent rounds of oxygen implantation, the order may be changed so that maskless oxygen implantation is performed in the second round of oxygen implantation or even later. In general, the process of forming a lithographically patterned oxygen implant mask and implanting oxygen into the structure, specifically either into an initial semiconductor substrate 100 or into the top semiconductor layer 230, may be repeated as many times as needed to provide the necessary variations in the thickness of the top semiconductor layer 230, and subsequently, variations in the vertical lengths of the resulting semiconductor fins.

The semiconductor top surface 237 is then cleaned. The structure containing the oxygen rich layer 220 is then annealed to convert the oxygen rich layer 220 into a buried oxide layer 220′, which contain a first portion 220A′ of the buried oxide layer 220′, a second portion 220B′ of the buried oxide layer 220′, and a third portion 220C′ of the buried oxide layer 220′ as shown in FIG. 2D (but not with a patterned resist 235 yet). The annealed structure at this point comprises the semiconductor substrate 210, the buried oxide layer 220′, and the top semiconductor layer 230. Unlike the structure according to the first embodiment at an equivalent stage as shown in FIG. 1C (excluding the patterned resist 135), the structure according to the second embodiment of the present invention at this point has a substantially flat “substrate top surface” 217, i.e., a first interface between the semiconductor substrate 210 and the buried oxide layer 220′. However, an “oxide top surface” 227, i.e., a second interface between the buried oxide layer 220′ and the top semiconductor layer 230 has multiple substantially different levels.

In the same manner as in the first embodiment of the present invention, the substrate top surface 217 is the same as the oxide bottom surface 217, which are used interchangeably herein. While the oxide bottom surface 217 is flat, the oxide top surface 227 has multiple levels and the thickness of the buried oxide layer 220′ varies from region to region depending on the level of the oxide top surface 217. Due to the differences in the implanted dose of the oxygen species, the amount of volume expansion also varies from region to region. According to the present invention, this variation is maintained at a reasonable level to keep the semiconductor top surface 237 substantially flat, or a chemical mechanical polish (CMP) is performed if the variation in the height of the semiconductor top surface 237 become noticeable to keep the semiconductor top surface 237 substantially flat,

A photoresist 235 is then applied to the semiconductor top surface 237 followed by a lithographic patterning as shown in FIG. 2D. As in the first embodiment, a thick insulator layer may optionally be formed on the semiconductor top surface 217, in which case the photoresist 235 is applied to the thick insulator layer and patterned. Subsequent pattern transfer into the top semiconductor layer 230 through a reactive ion etch (RIE) of the material forming the top semiconductor layer 230 selective to the underlying buried oxide layer 220′ forms semiconductor fins (250A-C) as shown in FIG. 2E. The semiconductor fins (250A-C) have different vertical lengths, that is, different distances between the fin top surface 259 of each of the semiconductor fins (250A-C) and the fin bottom surface 251 of the same semiconductor fin. In FIG. 2E, three types of semiconductor fins (250A-C), that is, a full vertical length semiconductor fins 250A, a medium vertical length semiconductor fins 250B, and a short vertical length semiconductor fins 250C, are shown. Preferably, the etch removes all of the unmasked portions of the top semiconductor layer but does not substantially remove the buried oxide layer.

The semiconductor fins (250A-C) according to the second embodiment have identical structure as the semiconductor fins (150A-C) according to the first embodiment of the present invention. The difference in the structure between the first and the second embodiment of the present invention lies between the structure of the buried oxide layer 220′ according to the second embodiment and the structure of the buried oxide layer 120′ according to the first embodiment. According to the first embodiment, the oxide bottom surface 117 (which is the same as substrate top surface 117) has at least two substantially different levels. According to the second embodiment, the oxide bottom surface 127 (which is the same as substrate top surface 217) is substantially flat.

According to both the first and the second embodiments, a gate dielectric 260 is formed on the sidewalls as shown in FIG. 2F. Gate conductor material is deposited and patterned to form gate electrodes 270. The parallel connection of the multiple finFETs is for demonstration only and one skilled in the art would find many standard variations in the configuration. Also, since the only structural difference between the first and the second embodiments is the structure of the buried oxide layer (120′ or 220′), which is still called a “buried oxide layer” although it is not buried at this point any more, one skilled in the art would readily recognize the equivalent structures for the first embodiment.

The gate dielectric 260 may be a thermally grown oxide or it may be a high-K dielectric material deposited by a chemical vapor deposition (CVD) or an atomic layer deposition (ALP). Preferably, the gate dielectric 260 comprises at least one material selected from the group consisting of SiO₂, oxynitride, HfO₂, ZrO₂, Al₂O₃, TiO₂, La₂O₃, SrTiO₃, LaAlO₃, and mixtures thereof.

The gate electrode 270 is located on and contacts the gate dielectric 260. The gate conductor stack may comprise a polysilicon layer, a stack of a polysilicon layer and a silicide layer or a stack containing a metal. Preferably, the gate electrode 270 is a metal gate electrode, in which the metal gate electrode is located on and contacts the gate dielectric and comprises at least one material selected from the group consisting of polysilicon, TaN, TiN, WN, other refractory metal nitrides, and mixtures thereof.

Depending on the formation of a thick insulator layer prior to the patterning of the semiconductor fins (150A-C or 250A-C) a double gate finFET or a triple gate finFET results. If a thick insulator layer is not used, triple gate finFETS are formed at this point, which have a channel on the top surface of the semiconductor fins. If a thick insulator layer is used, double gate finFETs are formed, which have channels only on the vertical sidewalls and not on the top surface of the semiconductor fins.

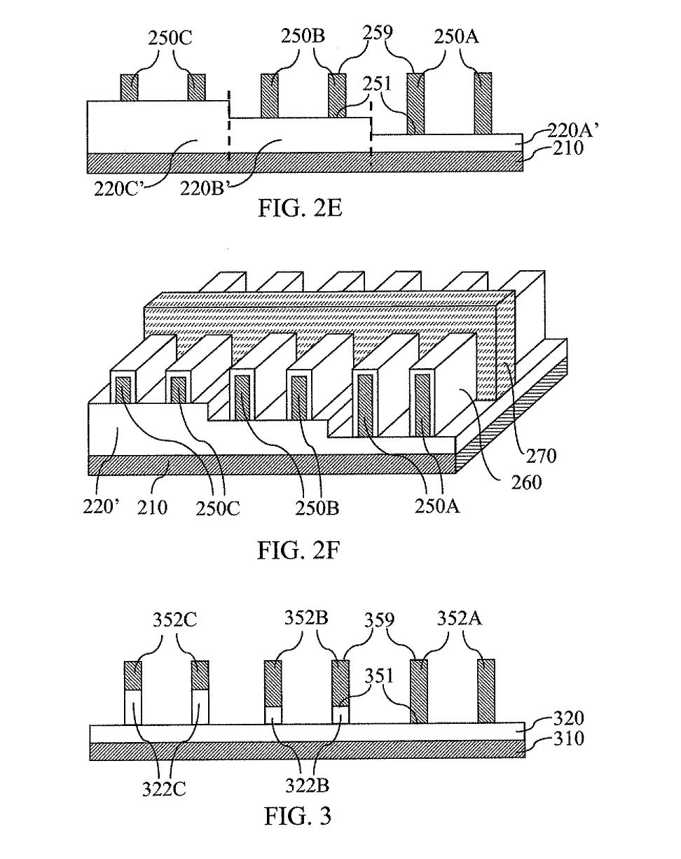

According to the third embodiment of the present invention, the methods for forming the structure according to the first or second embodiment of the present invention are followed with exactly the same structures until the formation of a buried oxide layer (120′ or 220′) is finished and the photoresist (135 or 235) on the top semiconductor layer (130 or 230) is lithographically patterned prior to the etch for the formation of at least two semiconductor fins (150A-C or 250A-C). According to the third embodiment of the present invention, a subsequent etch with a patterned photoresist (135 or 235) employs a non-selective reactive ion etching (RIE) that etches both the top semiconductor layer (130 or 230) and the buried oxide layer (120′ or 220′). An exemplary structure according to the third embodiment of the present invention is shown in FIG. 3. The etch removes all of the unmasked portions of the top semiconductor layer (130 or 230) and removes some of the buried oxide layer 320 under the unmasked portions of the top semiconductor layer (130 or 230). Preferably, the non-selective etch has a minimal difference between the etch rate of the material in the top semiconductor layer (130 or 230) and the etch rate of the buried oxide layer 320. Most preferably, the non-selective etch has no difference between the two etch rates. However, the present invention is practicable with an etch process with limited selectivity, in which case small steps are formed in the etched buried oxide layer 320 corresponding to the different levels of the oxide top surface (127 or 227) prior to the etch.

According to the third embodiment of the present invention, the etch results in at least two fins, each of which has an upper semiconductor portion (352A C) with a fin top surface 359. In other words, the top of each fin contains a semiconductor fin (150A-C or 250A-C) according to the first or second embodiment of the present invention. There may or may not be a fin that consists entirely of the upper semiconductor fin (352A-C). There is at least one fin that has a lower oxide portion (322B, 322C) that is disposed directly underneath the upper semiconductor portion (352A-C). In other words, at least one fin comprises an upper semiconductor portion (352A-C) which is a semiconductor fin, and a lower oxide portion (322B, 322C), which is an oxide fin, that is disposed directly underneath the upper semiconductor portion (352A-C).

In the example shown in FIG. 3, the two fins on the right side have only an upper semiconductor portion 352A in each of the fins. The upper semiconductor portion 352A in each of these two fins is equivalent to a full vertical length semiconductor fin (150A or 250A) in the first or the second embodiments. Each of the two fins in the middle comprises an upper semiconductor portion 352B and a lower oxide portion 322B. The upper semiconductor portion 352B in each of these two fins in the middle is equivalent to a medium vertical length semiconductor fin (150B or 250B) in the first or the second embodiments. Each of the two fins on the left side comprises an upper semiconductor portion 352C and a lower oxide portion 322C. The upper semiconductor portion 352C in each of these two fins on the left side is equivalent to a short vertical length semiconductor fin (150C or 250C) in the first or the second embodiments.

In a different perspective, the structures according to the third embodiment of the present invention is obtained by not stopping the etch of the top semiconductor layer (130 or 230) at the oxide top surface (127 or 227) with a selective etch but instead continuing the etch into at least a portion of the buried oxide layer 320 (equivalent to 120′ or 220′) with a non-selective etch. The apparent inclusion of the lower oxide portion into the fins thus obtained is an unavoidable consequence of such an etch process.

The resulting structure has at least two upper semiconductor portions (352A-C) that have different vertical lengths, that is, different distances between the top surface of the upper semiconductor portion, which is the fin top surface 359, and the bottom surface of the upper semiconductor portion, also called “upper semiconductor portion bottom surface” 351. The bottom of the fins maybe the bottom surface of the lower oxide portion (322B, 322C) if a lower oxide portion (322B, 322C) is part of the fin or may be the “upper semiconductor portion bottom surface” 351 of the upper semiconductor fin 352A if a lower oxide portion (322B, 322C) does not exist in a fin and the fin consists only of an upper semiconductor portion 352A.

Discussions on the epitaxial semiconductor structure in the first and the second embodiments equally apply to the third embodiment of the present invention. Other aspects of the third embodiment of the present invention that are not affected by the unique differences of the third embodiments apply to the third embodiment.

One of ordinary skill in the art would recognize the possibility of mixing the methods of the first and the second embodiments either spatially or sequentially in the process of forming buried oxide layers. Such modifications are explicitly contemplated herein.

One of ordinary skill in the art would also recognize that the implant species of oxygen herein may be replaced with other species, such as nitrogen, that are capable of forming an insulator layer with a sufficiently high dose and proper processing. Such modifications are also explicitly contemplated herein.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A semiconductor structure, comprising:
a semiconductor substrate;
an oxide layer located directly on said semiconductor substrate and having at least two different levels of an oxide top surface;
at least two semiconductor fins, each with a fin top surface and a fin bottom surface, wherein said fin top surfaces have substantially the same height and said fin bottom surfaces have substantially different heights and said fin bottom surfaces adjoin said oxide layer; and
at least two semiconductor finFETs which include said at least two semiconductor fins.

2. The semiconductor structure of claim 1, wherein
said semiconductor substrate is an epitaxial semiconductor substrate comprising a first epitaxial semiconductor material;
said at least two semiconductor fins comprise a second epitaxial semiconductor material; and
said first epitaxial semiconductor material and said second epitaxial semiconductor material have the same crystallographic orientations.

3. The semiconductor substrate of claim 2, wherein said semiconductor substrate has at least two different levels of substrate top surface and said buried oxide layer thickness is substantially the same except around boundaries where said at least two different levels are adjoined.

4. The semiconductor substrate of claim 2, wherein said semiconductor substrate has a substantially flat substrate top surface and said oxide layer has at least two substantially different oxide thicknesses.

5. A semiconductor structure, comprising:
a semiconductor substrate;
an oxide layer located directly on said semiconductor substrate;
at least two fins, each of said at least two fins having an upper semiconductor portion with a fin top surface and at least one of said at least two fins having a lower oxide portion disposed directly underneath said upper semiconductor portion, wherein said fin top surfaces have substantially the same heights, said upper semiconductor portions have different vertical lengths, and said at least two fins adjoin said oxide layer; and
at least two semiconductor finFETs which include said at least two fins.

6. The semiconductor structure of claim 5, wherein
said semiconductor substrate is an epitaxial semiconductor substrate comprising a first epitaxial semiconductor material;
said at least two upper semiconductor portions comprise a second epitaxial semiconductor material; and
said first epitaxial semiconductor material and said second epitaxial semiconductor material have the same crystallographic orientations.

7. The semiconductor substrate of claim 5, wherein said semiconductor substrate has a substantially flat substrate top surface and said oxide layer has substantially flat oxide top surface.
